(19) United States
(12) Patent Application Publication
(10) Pub. No.: US 2002/0017664 A1
(43) Pub. Date: Feb. 14, 2002

(54) PROTECTIVE LAYER FOR INTEGRATED CIRCUITS AND METHOD FOR THE MANUFACTURING THEREOF

(76) Inventors: ULRICH MUNCH, NEUCHATEL (CH); NIKLAUS SCHNEEBERGER, DUBENDORF (CH); DOMINIK JAEGGI, SAN FRANCISCO, CA (US)

Correspondence Address: GRIFFIN BUTLER WHISENHUNT & SZIPL LLP, SUITE PH-1, 2300 NINTH STREET SOUTH, ARLINGTON, VA, 222042396

(21) Appl. No.: 09/157,569

(22) Filed: Sep. 21, 1998

(30) Foreign Application Priority Data
Sep. 26, 1997 (CH) 2267/97

(51) Int. Cl. H01L 27/20; H01L 29/84

(52) U.S. Cl. 257/254

(57) ABSTRACT

The present invention concerns a structure (21) formed on a substrate (23) formed of a substrate material intended to be etched by a reactive agent, this structure including at least one first outer layer (29), or passivating layer, which has a first elastic property. This structure further includes at least one second outer layer (33) formed above the first layer, so that the second layer has a second elastic property which is different to the first elastic property. In the event that the second elastic property provides the second layer with greater elasticity in compression than the first layer, said structure has advantageously a yield higher than 99.8%.

The present invention concerns the field of integrated circuits and, more particularly, of protective layers for integrated circuits, and the methods for the manufacturing thereof.

Within the scope of certain specific applications, micromachining of a substrate formed of silicon is commonly performed, in particular via a wet etching process.

In the event that this substrate includes integrated circuits, such etching can only be performed after having manufactured the circuits, i.e. after the formation of a passivating layer. Indeed, certain components of the etching solution such as alkalines (for example the K+ ion) can contaminate the manufacturing process, and cause deterioration of the integrated circuits.

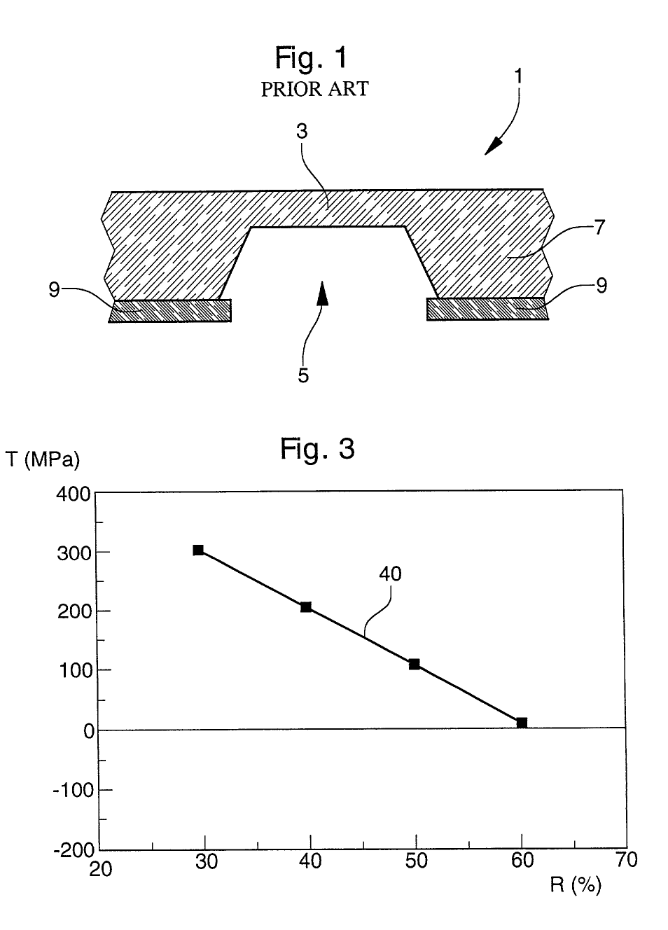

U.S. Pat. No. 5,387,316 discloses a pressure sensor. FIG. 1 of the present description shows such a sensor 1 including a membrane 3 which is formed by making a cavity 5 in a semiconductor substrate 7. Substrate 7 is formed of silicon, and cavity 5 is arranged by being etched in a solution formed of an etching agent such as KOH. Moreover, since silicon nitride cannot be etched by the KOH agent, a layer 9 is formed in silicon nitride to act as a mask during the etching of substrate 7 by KOH.

In the event that substrate 7 includes integrated circuits, the sensor then includes areas capable of being etched by the reactive agent of the etching solution for substrate 7. For example, substrate 7 can include connection pads formed of aluminium, able to be etched by the KOH agent. Consequently, it is necessary to protect such areas. Mechanical equipment, such as that described in the thesis of D. Jaeggi, <<Thermal Converters by CMOS Technology >>, ETH Zurich No 11567, pp. 58 and 59, are then conventionally used.

One drawback of micromachining a substrate of this type lies in the fact that it requires implementation of specific mechanical equipment for KOH etching.

Another drawback of using such equipment lies in the fact that it does not allow wafer by wafer process, which is contrary to the usual semiconductor industry concerns as to cost and yield.

As was mentioned hereinbefore, a passivating layer is formed on the substrate and the associated integrated circuits, to provide them with protection against chemical alterations such as from damp or contaminating agents, or against mechanical alteration such as by stress or dust.

Within the field of pressure sensors such as described in the aforecited U.S. Pat. No. 5,387,316, thin membranes subject to deformation are commonly used, so that they undergo internal forces which make them non plane. Consequently, a passivating layer generally made of silicon nitride, is then formed on such a membrane so as to make it plane. Indeed, a layer of silicon nitride causes considerable stress capable of acting on the substrate, in particular on the edges thereof. A layer of silicon nitride including small stress is therefore deposited. In other words, this layer must have elastic properties which give it elasticity in traction.

In this regard, it is to be recalled that simple traction (or compression) corresponds, according to the physics of the materials, to a single mechanical stress directed along a determined direction. Typically, in the case of a beam having a given axis of revolution, such stress is exerted along the direction of said axis. In other words, from a mathematical point, the stress tensor only includes one term and, in the space base formed of the principal stress directions, its matrix representation is diagonal.

In the case of a silicon substrate provided with a passivating layer of the aforementioned type, KOH etching of said substrate can cause various degradation.

Indeed, when such a passivating layer is made, it is then necessary to make areas of apeture through said layer, so as to be able to form an electric contact with the lower integrated circuits, in particular via connection pads. Typically, aluminium is used to make such pads. Those skilled in the art will note that the KOH agent can also etch the aluminium of exposed connection pads, which can cause deterioration of the integrated circuits to which said pads are connected.

Moreover, since KOH etching is of the anisotropic type, the lateral walls of the lines separating two successive chips can also be subject to an etch by the KOH agent, which can cause degradation of said chips.

Furthermore, the passivating layer can include holes into which the etching solution can be channelled. Consequently, the KOH agent can etch the lower layers, and cause possible integrated circuit degradation.

A good number of solutions have been proposed to overcome the aforementioned drawbacks. However, they have not, as yet, provided full satisfaction, with respect to the usual semiconductor industry concerns as to cost, yield and the environment.

By way of example, U.S. Pat. Nos. 4,155,866 and 4,113,551 disclose respectively the use of EDP (Ethylene Diamine Pyrocatechol) and TMAH (TetraMethylAmmoninium Hydroxide) to replace the KOH etching agent. One advantage of using the EDP or TMAH agent lies in the fact that these components etch silicon, but do not etch aluminium.

However, these agents have drawbacks which are not negligible, with regard to the aforementioned concerns.

Indeed, with respect to the KOH agent, the EDP and TMAH agents are more expensive and less stable. The Applicant of the present invention has observed that the stability of the KOH agent is of the order of several months and those of the TMAH and EDP agents is of the order of several hours and several minutes respectively. The Applicant of the present invention has also observed that, in the event that the aluminium layer is formed on a TiW layer used as diffusion barrier between the aluminium and the silicon, the TAMH agent can etch the TiW layer. Moreover, the EDP agent is supposedly able to be carcinogenic.

Also by way of example, an article entitled <<Fluorocarbon layer for protection from alkaline etchant >> by Y. Matsumoto, originating from a conference in Chicago entitled <<TRANSDUCERS 97 >>, describes the use of an additional protective layer formed of fluorocarbon on the passivating layer.

One drawback of using a component such as fluorocarbon lies in the fact that that latter requires additional equipment for the implementation thereof in an industrial environment where it is not commonly used.

Another drawback of using such a component lies in the fact that it is not compatible with the conventional photolithographic steps, since this component requires the use of a specific resist. Moreover, it has been observed that this resist is capable of becoming unstuck easily, so that it cannot be used as a photolithographic mask.

An object of the present invention is to provide a protective layer for integrated circuits on a substrate, said layer being resistant to the KOH reactive agent, and overcoming the aforementioned drawbacks.

Another object of the present invention is to provide such a layer which satisfies the conventional industrial criteria as to cost, yield and the environment, with respect to the materials used to form said layer.

Another object of the present invention is to provide a method able to manufacture such a protective layer, said method including known manufacturing steps, and allowing batch processing.

Another object of the invention is to provide such a method which satisfies the conventional industrial criteria as to cost, yield and the environment, with respect to conventional manufacturing processes

These objects, in addition to others, are achieved by the structure according to claim 1, and by the method according to claim 8 or 11.

One advantage of the second layer of the structure according to the invention is that it covers the different areas capable of being etched by the reactive agent such as KOH, in particular the aluminium connection pads, which provides the structure with protection against such agent. Consequently, this structure has a yield greater than 99.8%.

Another advantage of the second layer of the structure according to the present invention is that it provides resistance to the reactive agent, so that this structure can be processed in batches, i.e. without using specific mechanical equipment, unlike conventional structures.

Another advantage of the second layer according to the present invention is that it also covers the lateral walls of the lines separating two successive chips of the substrate, which gives the structure additional protection against said agent.

Another advantage of the second layer according to the present invention is that it also covers the holes of the first layer (i.e. the passivating layer), so that the etching solution cannot be channelled through these holes to the lower layers which are capable of being etched by the reactive agent, which gives the structure additional protection against said agent.

One advantage of the method according to the present invention is that it includes manufacturing steps, which are all known.

Another advantage of the method according to the present invention is that it enables the second layer of the structure to be formed by conventional photolithographic steps.

These objects, features and advantages, in addition to others, of the present invention will appear more clearly upon reading the detailed description of three preferred implementations of the invention, given solely by way of example, with reference to the annexed drawings, in which:

FIG. 1 already cited shows a schematic cross-sectional view of a conventional pressure sensor;

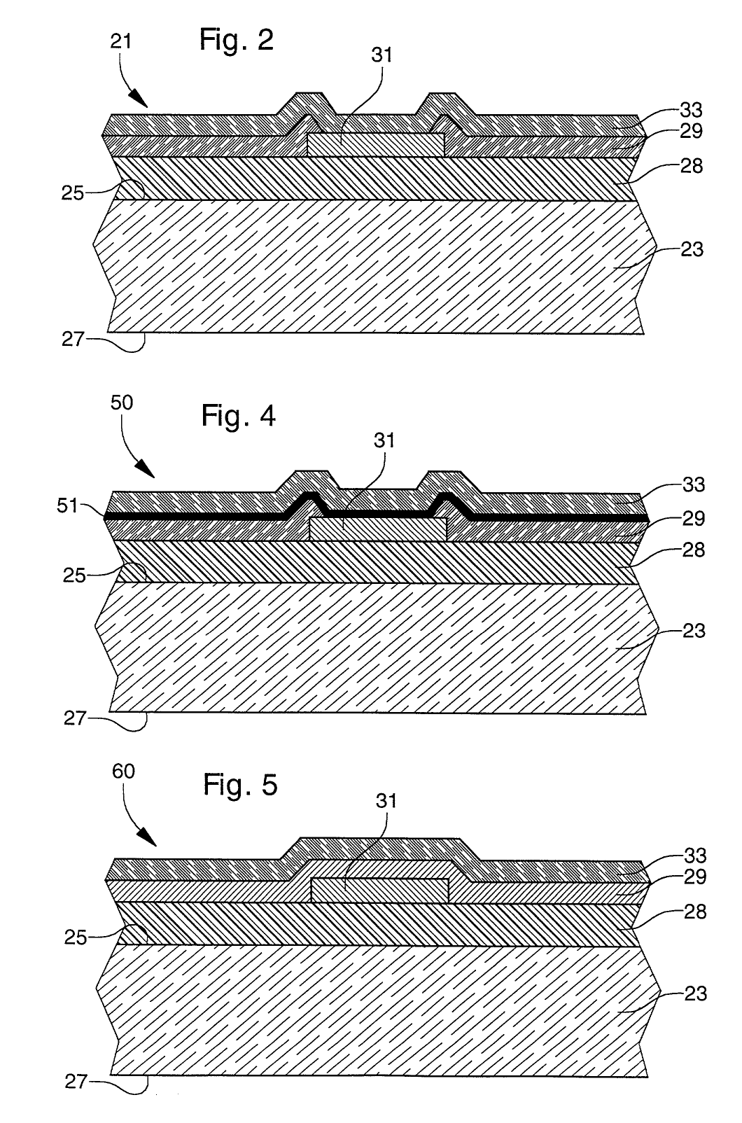

FIG. 2 shows a preferred embodiment of a structure according to the present invention;

FIG. 3 shows experimental data relating to residual stress as a function of different power percentage values, and linear regressions of said data;

FIG. 4 shows a first alternative embodiment of the structure of FIG. 2;

FIGS. 5 shows a second alternative embodiment of the structure of FIG. 2; and

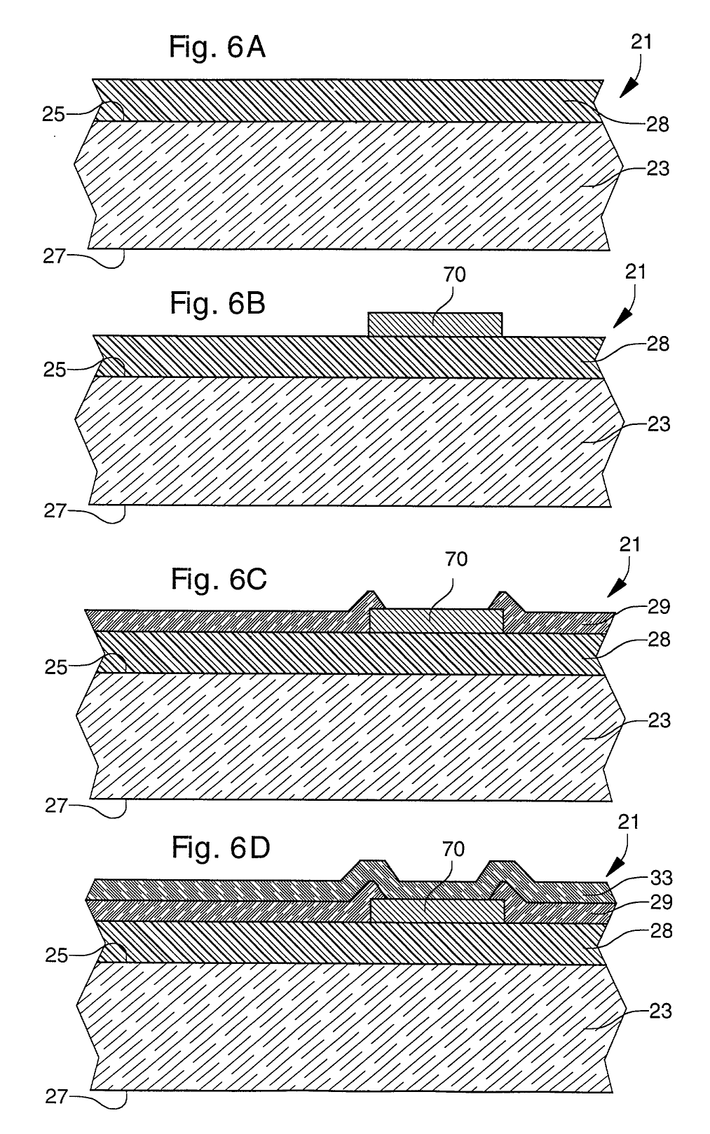

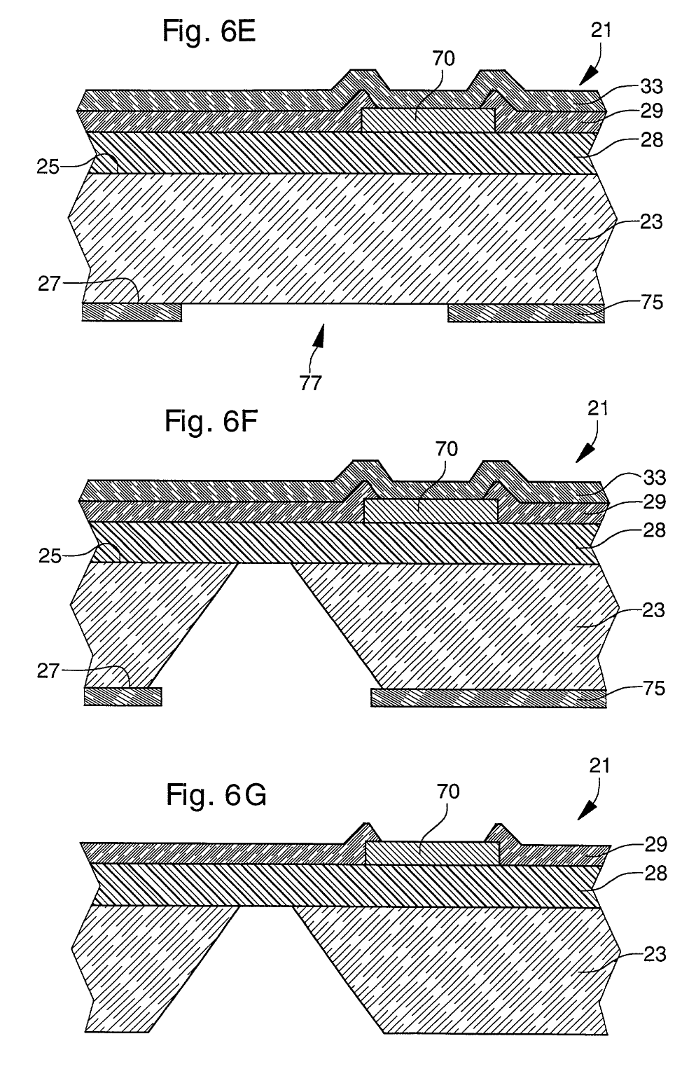

FIGS. 6A to 6G show schematic cross-sectional views of the structure of FIG. 2, during manufacturing.

FIG. 2 shows a preferred embodiment of a structure 21 according to the present invention.

Structure 21 is formed on a substrate 23 having a first face 25 or front face, and a second face 27 or rear face, and consists of a substrate material intended to be etched by a reactive agent A. This substrate material is preferably silicon, and agent A is KOH. Moreover, in the typical case of realisation of a pressure sensor of the aforementioned type, a layer 28 of silicon oxide is formed on face 25.

It will be noted, in the following description, that the terms front face and rear face can be defined for each of the layers which will be formed on substrate 23, so that all the front faces are situated on the same side as face 25, and all the rear faces are situated on the same side as face 27.

Structure 21 includes a first outer layer 29 which plays the role of passivating layer. Layer 29 is formed so as not to cover at least an area 31 formed of a material able to be etched by agent A.

Structure 21 also includes a second outer layer 33 formed on the front face of layer 29, so as to cover said face and, in particular, exposed area 31. In other words, structure 21 includes a double passivating layer.

One advantage of forming layer 33 of structure 21 lies in the fact that this structure is particularly resistant to the reactive agent such as KOH.

Indeed, it will be recalled that this agent can cause deterioration of the aluminium connection pads of such a structure, as was already mentioned hereinbefore. Thus, the resistance of a structure of this type to the KOH agent can thus be estimated from the number of connection pads which have deteriorated. In the remainder of the present description, yield is defined as the percentage of non deteriorated connection pads at the end of etching by KOH, with respect to the total number of pads formed on a given substrate. Typically, the yield of a structure according to the present invention is greater than 99.8%, this estimation having been performed on a sample of approximately 24,500 pads.

Moreover, since layer 33 covers the front face of structure 21, this layer also covers the lines separating two successive substrate chips, which provides the lateral faces of said lines with protection against an etch by the KOH agent.

Finally, since layer 33 covers the front face of structure 21, it also covers the holes of the passivating layer, i.e. of layer 29, into which the etching solution can be channelled, which provides the lower layers with protection against an etch by the KOH agent.

In other words, layer 33 protects structure 21 against an etch by the KOH agent.

Layers 29 and 33 are preferably formed of at least one material such as silicon nitride and oxinitride of silicon.

Moreover, layers 29 and 33 are also formed so as to have respectively a first elastic property and a second elastic property which differs from the first, as is described in more detail hereinafter.

In the typical case of realisation of a pressure sensor of the aforementioned type, face 27 of structure 21 shown in FIG. 2 is intended to undergo KOH etching, so as to form a thin membrane having a thickness substantially equal to the sum of that of layers 28 and 29. In this case, it is advantageous for the elastic properties of layer 29 to be such that it has greater elasticity in compression than the first layer, as will be described in more detail hereinafter.

By way of alternative, a portion of face 25 of substrate 23 can be intended to undergo etching by a reactive agent such as KOH, apertures or windows (not shown) having previously been provided through the lower layers such as layers 29 and 33, so that said portion to be etched is exposed. In such case, it is advantageous for the elastic properties of layer 33 to be such that it has greater elasticity in traction than layer 29.

It will be recalled that layers 29 and 33 can be formed by a plasma deposition technique, which is known. Such a plasma is created in a reactor by the simultaneous use of a low-frequency generator and a high-frequency generator. The reference LF designates the operating frequency of the low-frequency generator, and the reference HF designates the operating frequency of the high-frequency generator.

In particular, the stress of the layer to be formed is determined by the density and the ionic bombardment energy controlled by the two generators. It is possible to determine this stress by varying the power ratio between the frequencies LF and HF. Typically, an increase in the power provided at frequency LF provides the layer formed with greater elasticity in compression.

Purely by way of example, FIG. 3 illustrates such behaviour, in the case of silicon nitride layers deposited by a method of the aforementioned type.

FIG. 3 shows experimental data for the residual stresses T of said layers, as a function of different ratio values R between the power provided at frequency LF and the total power provided, and a linear regression designated 40 for such data. It will be noted in FIG. 3 that, when the power provided at frequency LF is increased, stress T decreases, which gives the layer greater elasticity in compression. It will also be noted that FIG. 3 is extracted from the aforecited thesis of D. Jaeggi.

It goes without saying that other deposition parameters such as the reactor pressure, the substrate temperature, and the partial pressures of the different gases present in the reactor, also influence the elastic properties of this layer. However, these parameters are predetermined for a conventional passivating layer, for example, in order to optimise the uniformity of said layer, and to reduce the number of undesirable holes passing through said layer.

Furthermore, the Applicant of the present invention has observed that the yield as defined hereinbefore, increases when the power provided at frequency LF is increased.

By way of improvement, FIGS. 4 and 5 show respectively first and second alternative embodiments of the structure of FIG. 2.

It will be noted that structures 50 and 60 shown in FIGS. 4 and 5 respectively, are close to structure 21 shown in FIG. 2. Thus, for purposes of simplicity, the layers shown in FIGS. 4 and 5, and designated by the same references as those shown in FIG. 2, are substantially identical to those designated in FIG. 2.

As FIG. 4 shows, structure 50 also includes an adhesion promoter layer 51 formed between layers 29 and 33, so as to increase the adhesion between layers 29 and 33, and to act as elasticity moderator. Layer 51 is preferably formed from a TEOS (Tetraetoxysilane) solution.

As FIG. 5 shows, structure 60 is formed so that layer 29 covers at least an area 31 formed of a material capable of being etched by agent A. Consequently, the front face of layer 33 is flat or plane above this area. In other words, such a structure advantageously decreases the step height which has to be covered by layer 33.

The structure according to the present invention such as described in relation to FIGS. 2, 4 or 5, can be made by a manufacturing method including several steps, each of which is known.

Purely by way of illustration, such a method for manufacturing structure 21 of FIG. 2 will now be described.

This method can comprise a sequence of seven consecutive steps designated <<a >> to <<g >> respectively. FIGS. 6A to 6G show schematic cross-sectional views of structure 21 during manufacturing, at the end of steps <<a >> to <<g >> respectively.

During step <<a >> silicon substrate 23 is formed with a face 25 or front face, and a face 27 or rear face. Then a silicon oxide layer 28 is deposited on face 25. FIG. 6A shows structure 21 at the end of step <<a >>.

Then, step <<a >> is followed by step <<b >>. During step <<b >>, a connection pad 70 is formed on the front face of layer 28. For this purpose, an aluminium layer is first deposited on the front face of layer 28. Then, the aluminium layer undergoes conventional photolithographic steps which consist in depositing a layer of photoresist on the front face of the aluminium layer, insulating and developing the photoresist layer, etching the exposed areas of the aluminium layer, and removing the remaining photoresist. FIG. 6B shows structure 21 at the end of step <<b >>.

Then step <<b >> is followed by step <<c >>. On the front face of layer 28 a silicon nitride layer 29 is formed by a plasma deposition method, so that layer 29 has a first elastic property, as is described in more detail hereinbefore. Then, a window 31 is made through layer 29, by photolithographic steps as described hereinbefore. FIG. 6c shows structure 21 at the end of step <<c >>.

Then step <<c >> is followed by step <<d >>. During step <<d >>, a silicon nitride layer 33 is formed on the front face of layer 29 by a similar deposition method to that implemented during step <<c >>. Layer 33 is formed so as to have elastic properties giving it greater elasticity in compression than layer 29. FIG. 6D shows structure 21 at the end of step <<d >>.

Then step <<d >> is followed by step <<e >>. During step <<e >>, a silicon nitride masking layer 75, which undergoes photolithographic steps such as described hereinbefore, is formed on face 27. At the end of these steps, a window 77 has been made in layer 75. FIG. 6E shows structure 21 at the end of step <<e >>.

Then step <<e >> is followed by step <<f >>. During step <<f >>, wet KOH etching is performed on the non covered portion of face 27 of substrate 23, so as to form a desired cavity in structure 21 for making, for example, a pressure sensor. FIG. 6F shows structure 21 at the end of step <<f >>.

Those skilled in the art will note that such etching no longer requires the use of specific mechanical equipment such as that described in the thesis of D. Jaeggi. It is no longer necessary to protect the front face of the substrate mechanically, against a potential etch by the K+ ions present in the etchant, since the areas capable of being etched by the KOH agent are covered by layer 33. In other words, the structure according to the present invention can be etched by the KOH agent, during batch processing, unlike conventional structures. This is particularly advantageous, given the usual semiconductor industry concerns as to cost and yield.

Then, step <<f >> is followed by step <<g >>. During step <<g >>, layer 33 and the remaining areas of layer 75 are etched, to remove them, by using, for example, an etching method of the R.I.E. (Reactive Ion Etching) type. FIG. 6G shows structure 21 at the end of step <<g >>.

By way of alternative, one can decide not to remove layer 33, in particular in the event that the structure according to the present invention does not include connection pads. Consequently, the elastic properties of layers 29 and 33 can be reversed with respect to those of structure 21 as described hereinbefore.

By way of improvement, the sequence of steps described hereinbefore in relation to FIGS. 6A to 6G can be modified, so as to be able to achieve the alternative embodiments of the structure of FIG. 2, i.e. structures 50 and 60 of FIGS. 4 and 5.

Let us consider the case of structure 50 of FIG. 4. In this case, an additional manufacturing step is inserted between step <<c >> and step <<d >>. During this additional step, an adhesion promoter layer 51 is formed on the front face of layer 29, by a similar deposition method to that implemented in step <<d >>. For this purpose, a TEOS solution can be used. Subsequently, steps <<d >> to <<g >> as described hereinbefore are performed. Moreover, step <<g >> is followed by a step <<h >>, during which layer 51 is removed by a known etching method.

Let us now consider the case of structure 60 of FIG. 5. In this case, the photolithographic steps of step <<c >> are not performed, so as not to form area of aperture 31 described hereinbefore in relation to FIG. 2 Next, step <<d >> is performed as described hereinbefore. Then, an additional manufacturing step is inserted between step <<d >> and step <<e >>. During this additional step, a window is formed in layer 33, above connection pad 70. Subsequently, steps <<e >> to <<g >> are performed as described hereinbefore. In particular, during step <<g >>, a window is formed through layer 29, and above connection pad 70.

By way of alternative, in the event that one wishes to etch a portion of the front face of a substrate of a structure according to the present invention, a manufacturing method including the following first and second steps can be provided. The first step consists in forming first layer 29, then second layer 33, so that the first and second layers do not cover a portion of the front face of the substrate. And the second step consists in etching by agent A the non covered portion of the front face of the substrate, so as to form a desired cavity, for example.

It goes without saying for those skilled in the art that the above detailed description can undergo various modifications without departing from the scope of the present invention. By way of example, other etching agents may be used, and materials other than silicon nitride suited to such agents. Also by way of example, one may form a structure according to the invention including, in addition to the first and second outer layers, additional passivating layers formed so that one of these layers has greater elasticity in compression than the other layers. In this case, it goes without saying that these layers can be formed other than of a single material such as silicon nitride and oxinitride of silicon.

What is claimed is:

1. A structure formed on a substrate having a first face, or front face, and a second face, or rear face, and formed of a substrate material intended to be etched by a reactive agent, this structure including at least one first outer layer, or passivating layer, which has a first elastic property, wherein said structure further includes at least one second outer layer formed above the first layer, so that the second layer has a second elastic property which is different to the first elastic property.

2. A structure according to claim 1, wherein the second elastic property provides the second layer with greater elasticity in compression than the first layer.

3. A structure according to claim 1, wherein the first layer is formed so as not to cover at least one area formed of a material capable of being etched by the reactive agent, and wherein the second layer of said structure covers said area.

4. A structure according to claim 1, further including an adhesion promoter layer formed between the first layer and the second layer.

5. A structure according to claim 4, wherein the adhesion promoter layer is formed of silicon nitride, from a TEOS solution.

6. A structure according to claim 1, wherein the first layer is formed so as to cover at least one area formed of a material capable of being etched by the reactive agent, and wherein the front face of the second layer is plane above said area.

7. A structure according to claim 1, wherein the first and second layers are formed of at least one material such as silicon nitride and oxinitride of silicon.

8. A method for manufacturing the structure according to claim 1, wherein said method is able to include steps consisting in forming at least one intermediate layer on the front face of the substrate, said method including a sequence of successive steps including:
a first step consisting in forming, on the front face of the substrate, the first layer ;
a second step consisting in forming, on the front face of the first layer, the second layer,
a third step consisting in forming, on the rear face of the substrate, a masking layer provided with a window ; and
a fourth step consisting in etching the non covered portion of the rear face of the substrate with the reactive agent.

9. A method according to claim 8, for manufacturing the structure according to claim 4, wherein said method further includes a fifth step which follows the first step and precedes the second step, the fifth step consisting in forming, on the front face of the first layer, the adhesion promoter layer.

10. A method according to claim 8, for manufacturing the structure according to claim 6, wherein the first step is replaced by a sixth step consisting in forming, on the front face of the substrate, the first layer so that this layer covers the front face of the substrate; and wherein it further includes a seventh step which follows the second step and precedes the third step, the seventh step consisting in forming an area of aperture in the second layer, above said area.

11. A method for manufacturing the structure according to claim 1, said method including a sequence of successive steps comprising:
a first step consisting in forming the first layer, then the second layer so that the first and second layers do not cover a portion of the front face of the substrate; and
a second step consisting in etching, with the reactive agent, the non covered portion of the front face of the substrate.
